(19) United States
(12) Patent Application Publication
(10) Pub. No.: US 2025/0046624 A1
(43) Pub. Date: Feb. 6, 2025

(54) METHOD OF PROCESSING WAFER

(71) Applicant: DISCO CORPORATION, Tokyo (JP)

(72) Inventor: Akira MIZUTANI, Tokyo (JP)

(21) Appl. No.: 18/765,483

(22) Filed: Jul. 8, 2024

(30) Foreign Application Priority Data
Jul. 31, 2023 (JP) 2023-124385

(51) Int. Cl. H01L 21/56; H01L 21/304; H01L 21/67; H01L 21/687

(52) U.S. Cl. CPC H01L 21/561; H01L 21/304; H01L 21/67092; H01L 21/68764

(57) ABSTRACT

A method of processing a wafer includes holding the wafer on a chuck table while exposing a reverse side of the wafer, grinding the reverse side of the wafer with a grinding wheel that has an annular array of grindstones and that is smaller in diameter than the wafer, while positioning the grinding wheel radially inwardly of an excessive outer circumferential region, thereby grinding the effective region to a predetermined thickness to leave the excessive outer circumferential region as a ring-shaped ridge, before or after the grinding step, forming separation initiating points in the wafer for separating the excessive outer circumferential region from the effective region, and applying external forces to the ring-shaped ridge of the wafer in which the separation initiating points have been formed, to remove a chamfered edge together with the excessive outer circumferential region from the wafer.

### BACKGROUND OF THE INVENTION

### Field of the Invention

The present invention relates to a method of processing a wafer having on a face side thereof an effective region and an excessive outer circumferential region surrounding the effective region with a chamfered edge formed on the outer circumference of the excessive outer circumferential region.

### Description of the Related Art

Wafers with a plurality of devices such as integrated circuits (ICs) and large scale integration (LSI) circuits constructed on their face sides in respective areas demarcated by a plurality of projected dicing lines established thereon have their reverse sides ground by a grinding apparatus until they are thinned down to a predetermined thickness. Thereafter, the wafers are divided into individual device chips by a dicing apparatus or a laser processing apparatus. The device chips thus fabricated will be used in electronic appliances including cellphones and personal computers.

A wafer has a chamfered edge on its outer circumference. When the reverse side of the wafer is ground to thin the wafer down, the chamfered edge is turned into a sharp knife edge shape that may inflict injury on an operator who handles the wafer or allow cracks to develop into the wafer from its outer circumference, tending to cause damage to the wafer.

There has been proposed as a solution to the above problems a technology for irradiating a wafer with a laser beam having a wavelength transmittable through the wafer while positioning a focused spot of the laser beam inwardly of a chamfered edge of the wafer to thereby form a ring-shaped modified layer in the wafer, so that the chamfered edge can be removed from the wafer along the modified layer functioning as division initiating points (see, for example, JP 2022-174036A).

### SUMMARY OF THE INVENTION

However, since the wafer to be processed has a relatively large thickness in the range from 700 to 800 μm, it is not easy to remove the chamfered edge from the wafer even though the modified layer is formed in the wafer.

In addition, the above technology may fail on occasion to fully remove the chamfered edge from the wafer and leave a part of the chamfered edge on the wafer. The remaining part of the chamfered edge may fall off and become a contaminant or may be responsible for chippings from individual device chips at the time the wafer is divided into those device chips in a subsequent process.

It is therefore an object of the present invention to provide a method of processing a wafer while solving the problems of a part of a chamfered edge left on the wafer in a chamfered edge removing step carried out thereon and falling off as a contaminant or being responsible for chippings from individual device chips at the time the wafer is divided into those device chips.

In accordance with an aspect of the present invention, there is provided a method of processing a wafer having on a face side thereof an effective region and an excessive outer circumferential region surrounding the effective region with a chamfered edge formed on an outer circumference of the excessive outer circumferential region. The method includes a holding step of holding the wafer on a chuck table while exposing a reverse side of the wafer, a grinding step of grinding the reverse side of the wafer with a grinding wheel that has an annular array of grindstones and that is smaller in diameter than the wafer, while positioning the grinding wheel radially inwardly of the excessive outer circumferential region, thereby grinding the effective region to a predetermined thickness to leave the excessive outer circumferential region as a ring-shaped ridge, before or after the grinding step, a separation initiating point forming step of forming separation initiating points in the wafer for separating the excessive outer circumferential region from the effective region, and a chamfered edge removing step of applying external forces to the ring-shaped ridge of the wafer in which the separation initiating points have been formed, to remove the chamfered edge together with the excessive outer circumferential region from the wafer.

Preferably, the chamfered edge removing step includes holding the wafer on a spinner table and rotating the spinner table to apply centrifugal forces as the external forces to the ring-shaped ridge to remove the chamfered edge together with the excessive outer circumferential region from the wafer. Preferably, the separation initiating point forming step is carried out before the grinding step, and the grinding step includes applying external forces from the grinding wheel to the ring-shaped ridge of the wafer to remove the chamfered edge together with the excessive outer circumferential region from the wafer.

Preferably, the wafer is a bonded wafer including a wafer having the effective region and another wafer bonded to the wafer with the effective region facing the other wafer. Preferably, the separation initiating point forming step includes applying a laser beam having a wavelength transmittable through the wafer to the wafer while positioning a focused spot of the laser beam in a boundary zone between the effective region and the excessive outer circumferential region to form a ring-shaped modified layer in the boundary zone. Preferably, the method further includes, after the chamfered edge removing step, a finishingly grinding step of further grinding the reverse side of the wafer to reduce a thickness of the wafer to a predetermined finished thickness. Preferably, the effective area of the wafer is a device region including a plurality of devices formed in respective areas demarcated by a grid of projected dicing lines.

According to the present invention, it is relatively easy to remove the ring-shaped ridge made up of the excessive outer circumferential region including the chamfered edge from the wafer. Therefore, the difficulty in removing the excessive outer circumferential region including the chamfered edge is eliminated. Inasmuch as it is easy to remove the chamfered edge, the chamfered edge is prevented from remaining on the outer circumference of the wafer. Accordingly, the problems of a part of the chamfered edge left on the wafer and falling off as a contaminant or being responsible for chippings from individual device chips at the time the wafer is divided into those device chips are solved.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view of a bonded wafer as a workpiece according to an embodiment of the present invention;

FIG. 1B is a perspective view of a simplex wafer as a workpiece according to an embodiment of the present invention;

FIG. 2A is a perspective view illustrating the manner in which the bonded wafer is held on a chuck table of a laser processing apparatus that carries out a separation initiating point forming step;

FIG. 2B is a perspective view illustrating the manner in which separation initiating points are formed in the bonded wafer by the laser processing apparatus illustrated in FIG. 2A;

FIG. 3A is an enlarged fragmentary cross-sectional view illustrating the configuration of a modified layer of Type 1 that acts as separation initiating points;

FIG. 3B is an enlarged fragmentary cross-sectional view illustrating the configuration of another modified layer of Type 2 that acts as separation initiating points;

FIG. 3C is an enlarged fragmentary cross-sectional view illustrating the configuration of still another modified layer of Type 3 that acts as separation initiating points;

FIG. 4 is a perspective view illustrating the manner in which a chamfered edge removing step is carried out along with a grinding step;

FIG. 5 is a perspective view illustrating the manner in which the grinding step is carried out prior to the separation initiating point forming step;

FIG. 6A is a perspective view illustrating the manner in which the separation initiating point forming step is carried out subsequently to the grinding step;

FIG. 6B is an enlarged fragmentary cross-sectional view illustrating the configuration of separation initiating points formed in the bonded wafer in the separation initiating point forming step illustrated in FIG. 6A;

FIG. 7A is an enlarged fragmentary cross-sectional view illustrating the manner in which a ring-shaped ridge formed on the bonded wafer is housed in external force applying means that applies external forces to the ring-shaped ridge;

FIG. 7B is an enlarged fragmentary cross-sectional view illustrating the manner in which the external force applying means illustrated in FIG. 7A is flipped over to remove a chamfered edge from the bonded wafer;

FIG. 8 is an exploded perspective view of a chamfered edge removing apparatus that removes the chamfered edge from the bonded wafer by applying external forces to the ring-shaped ridge on the bonded wafer;

FIG. 9 is a side elevational view illustrating the manner in which the chamfered edge removing step is carried out by the chamfered edge removing apparatus illustrated in FIG. 8, the chamfered edge removing apparatus being partly depicted in cross section; and

FIG. 10 is a perspective view illustrating the manner which a finishingly grinding step is carried out.

### DETAILED DESCRIPTION OF THE PREFERRED EMBODIMENT

A method of processing a wafer according to a preferred embodiment of the present invention will be describe in detail below with reference to the accompanying drawings.

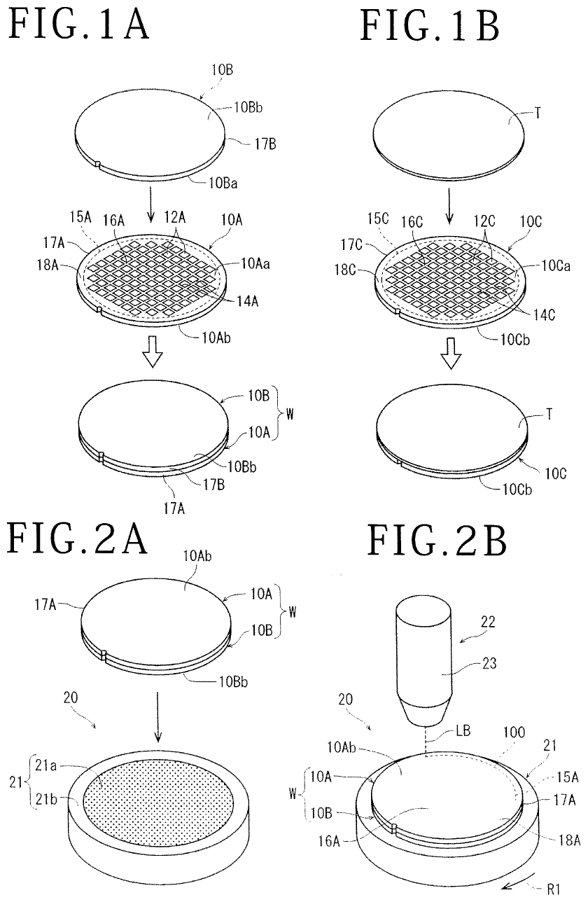

FIG. 1A illustrates, in perspective, a bonded wafer W as a workpiece that can be processed by the method of processing a wafer according to the present embodiment. As illustrated in FIG. 1A, the bonded wafer W refers to a disk-shaped wafer assembly made up of a first wafer 10A and a second wafer 10B that are affixed to each other. The first wafer 10A is a silicon wafer having a diameter of 300 mm and a thickness of 700 μm, for example, and includes a plurality of devices 12A, to be finally available as products, constructed in respective areas demarcated on a face side 10Aa thereof that faces upwardly by a grid of projected dicing lines 14A established thereon. The first wafer 10A has the face side 10Aa and a reverse side 10Ab opposite the face side 10Aa. The first wafer 10A is an effective region, also referred to as a device region, 16A positioned centrally on the face side 10Aa and containing the devices 12A therein and an excessive outer circumferential region 18A positioned on the face side 10Aa and surrounding the effective region 16A. The first wafer 10A also includes a chamfered edge 17A formed on the outer circumference of the excessive outer circumferential region 18A and a boundary zone 15A positioned between the effective region 16A and the chamfered edge 17A and separating the effective region 16A and the excessive outer circumferential region 18A from each other.

The boundary zone 15A is added for illustrative purposes and is not actually defined on the first wafer 10A. In addition, the boundary zone 15A is not limited to an annular line and has a certain radial extent on the first wafer 10A. The second wafer 10B is structurally identical to the first wafer 10A in that it includes a silicon wafer having a plurality of devices formed in respective areas demarcated on a face side 10Ba thereof that faces downwardly by a grid of projected dicing lines established thereon. The bonded wafer W is made structurally integral by a siloxane bond achieved by affixing the effective region 16A of the face side 10Aa of the first wafer 10A and the face side Ba of the second wafer 10B to each other and heat-treating them, for example.

FIG. 1B illustrates, in perspective, another wafer 10C as a workpiece that can be processed by the method of processing a wafer according to the present embodiment. The wafer 10C includes a simplex wafer with a protective tape T affixed to a face side 10Ca thereof. The illustrated wafer 10C, which is identical in structure to the first wafer 10A illustrated in FIG. 1A, includes a silicon wafer having a diameter of 300 mm and a thickness of 700 μm, for example, and includes a plurality of devices 12C, to be finally available as products, constructed in respective areas demarcated on the face side 10Ca by a grid of projected dicing lines 14C established thereon. The wafer 10C has the face side 10Ca and a reverse side 10Cb opposite the face side 10Ca. The wafer 10C includes an effective region 16C positioned centrally on the face side 10Ca and containing the devices 12C therein and an excessive outer circumferential region 18C positioned on the face side 10Ca and surrounding the effective region 16C. The wafer 10C also includes a chamfered edge 17C formed on the outer circumference of the excessive outer circumferential region 18C and a boundary zone 15C positioned between the effective region 16C and the chamfered edge 17C and separating the effective region 16C and the excessive outer circumferential region 18C from each other. As with the boundary zone 15A, the boundary zone 15C is added for illustrative purposes and is not actually defined on the wafer 10C. When the wafer 10C is processed by the method of processing a wafer according to the present embodiment, the protective tape T affixed to the face side 10Ca of the wafer 10C functions as a protective member for protecting the devices 12C in the effective region 16C.

Wafers that can be processed by the method of processing a wafer according to the present embodiment are not limited to the bonded wafer W and the simplex wafer 10C described above, and may include various wafers each having an effective region and a chamfered edge on the outer circumference of an excessive outer circumferential region surrounding the effective region. For example, a wafer that can be processed by the method may be a wafer of gallium nitride (GaN), a wafer of gallium arsenide (GaAs), a wafer of lithium tantalate (LiTaO₃), a wafer of lithium niobate (LiNbO₃), or a wafer such as a glass wafer whose central region referred to as an effective region is free of devices and that will subsequently be processed into products. According to the present embodiment, the method of processing the bonded wafer W as a wafer or workpiece will be described in detail below.

The method of processing a wafer, i.e., the bonded wafer W, according to the present embodiment includes a holding step of holding the bonded wafer W on a chuck table, to be described later, while exposing the reverse side of the bonded wafer W, i.e., the reverse side 10Ab of the first wafer 10A, upwardly, a grinding step of positioning a grinding wheel, to be described later, including an annular array of grindstones and having a diameter smaller than that of the bonded wafer W, radially inwardly of a region corresponding to the excessive outer circumferential region 18A, i.e., the boundary zone 15A, and grinding the reverse side 10Ab of the first wafer 10A to grind a region corresponding to the effective region 16A to a predetermined thickness, leaving a ring-shaped ridge in the excessive outer circumferential region 18A, a separation initiating point forming step, before or after the grinding step, of forming separation initiating points along which the excessive outer circumferential region 18A including the chamfered edge 17A is to be separated from the effective region 16A, and a chamfered edge removing step of applying external forces to the ring-shaped ridge of the bonded wafer W to remove the chamfered edge 17A along with the excessive outer circumferential region 18A from the bonded wafer W.

According to the present invention, the steps referred to above of the method of processing a wafer may be switched around appropriately in sequence. A specific sequence of the method of processing a wafer according to the present embodiment will be described in detail below with reference to the drawings.

According to the present embodiment, the separation initiating point forming step of forming separation initiating points along which the excessive outer circumferential region 18A is to be separated from the effective region 16A is carried out before the grinding step. In preparation for the separation initiating point forming step, the bonded wafer W is transported to a laser processing apparatus 20 partly illustrated in FIGS. 2A and 2B. The laser processing apparatus 20 includes at least a chuck table 21 illustrated in FIG. 2A and a laser beam applying unit 22 illustrated in FIG. 2B. The chuck table 21 includes a suction chuck 21a made of an air-permeable material and providing a holding surface and a frame 21b surrounding the suction chuck 21a. The laser beam applying unit 22 includes a laser oscillator, not depicted, for emitting a laser beam LB having a wavelength transmittable through the first wafer 10A of the bonded wafer W, and a beam condenser 23 for converging and applying the laser beam LB emitted from the laser oscillator to the bonded wafer W. The laser processing apparatus 20 further includes a moving mechanism, not depicted, for moving the chuck table 21, a rotating mechanism, not depicted, for rotating the chuck table 21 about its central axis, and suction means, not depicted, for generating and applying a negative pressure to the suction chuck 21a.

After the bonded wafer W has been transported to the laser processing apparatus 20, the bonded wafer W is placed on the chuck table 21 with the first wafer 10A, which provides a reverse side of the bonded wafer W, facing upwardly and the second wafer 10B facing downwardly, and then the suction means is actuated to apply the negative pressure to the suction chuck 21a, holding the bonded wafer W under suction on the chuck table 21. Then, an alignment process is performed on the bonded wafer W held under suction on the chuck table 21, using an alignment unit and a height detector, both not depicted, of the laser processing apparatus 20. In the alignment process, the position of an outer circumferential end of the first wafer 10A where the chamfered edge 17A is located and the position of the center of the first wafer 10A are detected. Further, the height of the reverse side 10Ab of the first wafer 10A is detected, and a processing position in the boundary zone 15A on the first wafer 10A that is to be irradiated with the laser beam LB is detected.

Separation initiating points to be formed in the first wafer 10A in the separation initiating point forming step may be of configurations of Types 1 through 3 to be described below.

### (Type 1)

On the basis of the detected position of the outer circumferential end of the first wafer 10A where the chamfered edge 17A is located and the detected position of the center of the first wafer 10A, a position in the first wafer 10A that is annularly established in the boundary zone 15A at a radius of 147 mm from the center of the first wafer 10A, inside of the excessive outer circumferential region 18A on which the chamfered edge 17A is present, e.g., a region spaced 0.5 mm from the outer circumferential end of the first wafer 10A, from the outer circumferential end of the first wafer 10A, is detected as a predetermined processing position where a modified layer is to be formed by a laser processing operation of the laser processing apparatus 20. The information of the processing position thus detected is stored in a controller, not depicted.

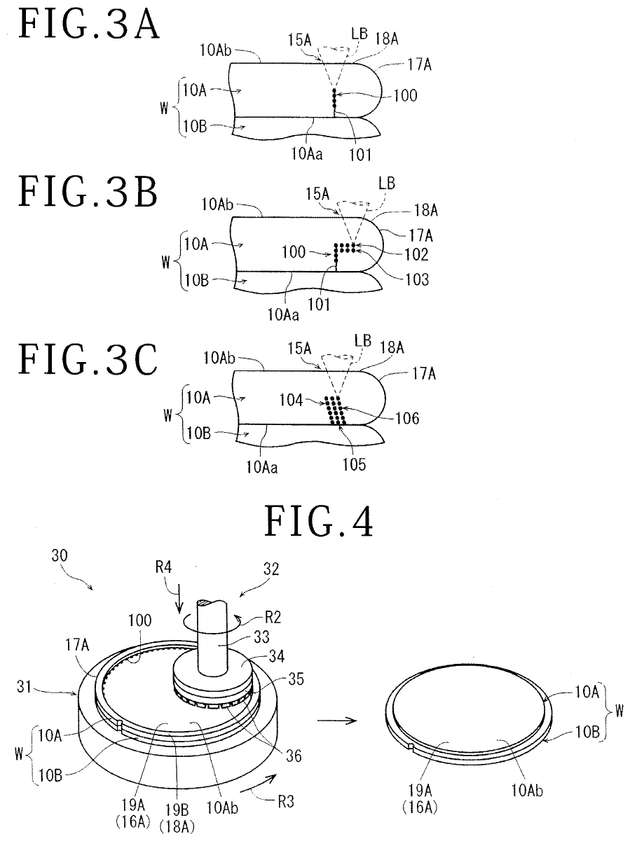

Thereafter, on the basis of the information of the processing position detected in the alignment process, the chuck table 21 is moved to place the processing position immediately below the beam condenser 23 of the laser beam applying unit 22, as illustrated in FIG. 2B. Then, the laser beam applying unit 22 applies the laser beam LB transmittable through the first wafer 10A to the reverse side 10Ab thereof while positioning the focused spot of the laser beam LB within the boundary zone 15A between the effective region 16A and the excessive outer circumferential region 18A including the chamfered edge 17A. At the same time, the chuck table 21 is rotated about its central axis in the direction indicated by an arrow R1, during which time the laser beam LB forms a modified layer 100 (see FIG. 3A) acting as separation initiating points within the first wafer 10A fully circumferentially along the chamfered edge 17A of the first wafer 10A.

As illustrated in FIG. 3A, when the modified layer 100 is formed in the first wafer 10A, cracks are developed from the modified layer 100 at a relatively deep position where the cracks reach the face side 10Aa of the first wafer 10A. Moreover, the modified layer 100 is made up of a plurality of annular sublayers arrayed vertically, e.g., four annular modified sublayers arrayed vertically. The modified layer 100 made up of a plurality of sublayers is formed as follows. First, the laser beam LB is applied to the first wafer 10A while its focused spot is being positioned at a depth close to the face side 10Aa in the boundary zone 15A of the first wafer 10A, and the chuck table 21 is rotated about its central axis as described above, forming a first annular sublayer in and along the boundary zone 15A. Thereafter, while the chuck table 21 is being rotated, the laser beam LB is applied to the first wafer 10A while its focused spot is being positioned at three successively reduced depths in the boundary zone 15A, thereby forming three successive annular sublayers in and along the boundary zone 15A. In this manner, a vertical array of four successive annular sublayers are formed in and along the boundary zone 15A, making up the modified layer 100. The modified layer 100 thus formed is referred to as a modified layer of Type 1.

### (Type 2)

Separation initiating points of Type 2 to be described below include, as illustrated in FIG. 3B, a combination of the modified layer 100 of Type 1 and annular modified layers 102 and 103 formed at different depths in the boundary zone 15A by applying the laser beam LB to the first wafer 10A while positioning its focused spot in positions radially outside of and adjacent to the modified layer 100 of Type 1 and rotating the chuck table 21 about its central axis. As illustrated in FIG. 3B, each of the modified layers 102 and 103 is made up of a plurality of annular sublayers located at a depth radially outside of and adjacent to the modified layer 100. Specifically, while the chuck table 21 is being rotated, the laser beam LB is applied to the first wafer 10A while its focused spot is being positioned at three successively horizontally spaced positions spaced radially outwardly from the modified layer 100 of Type 1, thereby forming three successive annular sublayers in and along the boundary zone 15A. In this manner, separation initiating points of Type 2 are formed in and along the boundary zone 15A, made up of the modified layers 100, 102, and 103.

### (Type 3)

Separation initiating points of Type 3 to be described below are different from the modified layers of Types 1 and 2 described above as follows. As illustrated in FIG. 3C, the chuck table 21 is rotated about its central axis and the laser beam LB is applied to the first wafer 10A while positioning the focused spot of the laser beam LB at a greatest depth next to the face side 10Aa in the boundary zone 15A, thereby forming a first annular modified sublayer in the boundary zone 15A along the chamfered edge 17A. Thereafter, the chuck table 21 is rotated about its central axis and the laser beam LB is applied to the first wafer 10A while positioning the focused spot of the laser beam LB at successively reduced depths closer to the reverse side 10Ab, i.e., an upper surface of the first wafer 10A, in positions successively closer to the center of the first wafer 10A, i.e., successively shifted to the left in FIG. 3C, in the boundary zone 15A, thereby forming successive annular modified sublayers in the boundary zone 15A along the chamfered edge 17A. In this manner, a modified layer 104 made up of these successive annular modified sublayers, which is progressively inclined toward the center of the first wafer 10A in an upward direction, is formed in an annular pattern in the boundary zone 15A along the chamfered edge 17A. Furthermore, additional annular inclined modified layers 105 and 106 are similarly formed in the boundary zone 15A along the chamfered edge 17A at positions spaced radially outwardly from the modified layer 104, i.e., closer to the chamfered edge 17A, as illustrated in FIG. 3C. In this manner, separation initiating points of Type 3 are formed in and along the boundary zone 15A, made up of the modified layers 104, 105, and 106.

Laser processing conditions in the separation initiating point forming step thus carried out are established, for example, as follows.

Wavelength: 1099 nm

Repetitive frequency: 80 kHz

Average output power: 2.0 W

Processing feed speed: 450 mm/s

or

Wavelength: 1342 nm

Repetitive frequency: 90 kHz

Average output power: 1.9 W

Processing feed speed: 400 mm/s

Separation initiating points formed according to the present invention are not limited to the configurations of Types 1, 2, and 3 described above, and may be those capable of functioning to remove the chamfered edge 17A in the chamfered edge removing step to be described later. For example, any two or more of the modified layers of Types 1, 2, and 3 may be combined together, or other modified layers may be used as separation initiating points. According to the present embodiment, the processing of the bonded wafer W where the modified layer 100 of Type 1 are formed as separation initiating points in the first wafer 10A will be described below.

After the separation initiating point forming step has been carried out on the bonded wafer W, as described above, the bonded wafer W is transported to a grinding apparatus 30 partly illustrated in FIG. 4. As illustrated in FIG. 4, the grinding apparatus 30 includes a chuck table 31 rotatable about its central axis while holding the bonded wafer W thereon, the chuck table 31 being fluidly connected to suction means, not depicted, and a grinding unit 32 for grinding the bonded wafer W held on the chuck table 31. The grinding unit 32 includes a spindle 33 that is rotatable about its central axis and can also be vertically movable, i.e., lifted and lowered, a wheel mount 34 mounted on a lower distal end of the spindle 33 and rotatable about its central axis upon rotation of the spindle 33, and a grinding wheel 35 mounted on a lower surface of the wheel mount 34 and smaller in diameter than the bonded wafer W, the grinding wheel 35 supporting on its lower surface an annular array of grindstones 36.

The bonded wafer W that has been transported to the grinding apparatus 30 is placed on the chuck table 31 with the reverse side 10Ab of the first wafer 10A being exposed upwardly. Then, the suction means, not depicted, fluidly connected to the chuck table 31 is actuated to hold the bonded wafer W under suction on the chuck table 31 (holding step).

Then, as illustrated in FIG. 4, the spindle 33 is rotated about its central axis in the direction indicated by an arrow R2 at a predetermined speed of 6,000 rpm, for example. At the same time, the chuck table 31 is rotated about its central axis in the direction indicated by an arrow R3 at a predetermined speed of 300 rpm, for example. The grinding wheel 35 that is rotating in unison with the spindle 33 is lowered in the direction indicated by an arrow R4 to bring the grindstones 36 into contact with the reverse side 10Ab of the first wafer 10A. Specifically, the grindstones 36 are brought into a region of the reverse side 10Ab that is coextensive with the effective or device region 16A, and grinding-fed, i.e., lowered, in the direction indicated by the arrow R4 at a rate of 1.0 μm/s, for example. In this fashion, the grindstones 36 are kept in abrasive contact with the reverse side 10Ab of the first wafer 10, thereby performing a grinding process on the first wafer 10A. In this grinding process, the grindstones 36 grind a central region of the reverse side 10Ab radially inside of the boundary zone 15A where the modified layer 100 is present, leaving unground an outer region of the reverse side 10Ab that is coextensive with the excessive outer circumferential region 18A including the chamfered edge 17A. As a result, as illustrated in a left section of FIG. 4, a recess 19A is formed in the central region of the reverse side 10Ab that is commensurate with the effective region 16A, leaving a ring-shaped ridge 19B in the outer region of the reverse side 10Ab that is coextensive with the excessive outer circumferential region 18A, the ring-shaped ridge 19B being raised stepwise from the bottom of the recess 19A (grinding step).

According to the present embodiment, as described above, the separation initiating point forming step has been carried out on the first wafer 10A of the bonded wafer W prior to the grinding step, forming the modified layer 100 in the boundary zone 15A between the effective region 16A and the excessive outer circumferential region 18A including the chamfered edge 17A as separation initiating points for separating the effective region 16A and the excessive outer circumferential region 18A from each other. As the grinding process progresses in the grinding step, the recess 19A is formed in the reverse side 10Ab of the first wafer 10A, leaving the ring-shaped ridge 19B around the recess 19A. As a result, the grinding wheel 35 with the grindstones 36 mounted thereon effectively applies external forces to the ring-shaped ridge 19B. The external forces thus applied break the excessive outer circumferential region 18A including the chamfered edge 17A along the modified layer 100, separating the excessive outer circumferential region 18A from the effective region 16A. As illustrated in a right section of FIG. 4, the chamfered edge 17A together with the excessive outer circumferential region 18A is removed from the first wafer 10A (chamfered edge removing step).

According to the present embodiment described above, the separation initiating point forming step is carried out prior to the grinding step, and then the grinding step and the chamfered edge removing step are carried out. However, the present invention is not limited to such a sequence of steps. After the grinding step has been carried out, the separation initiating point forming step may be carried out, after which the chamfered edge removing step may be carried out, for example. A method of processing a wafer by carrying out the grinding step and thereafter carrying out the separation initiating point forming step and the chamfered edge removing step will be described below.

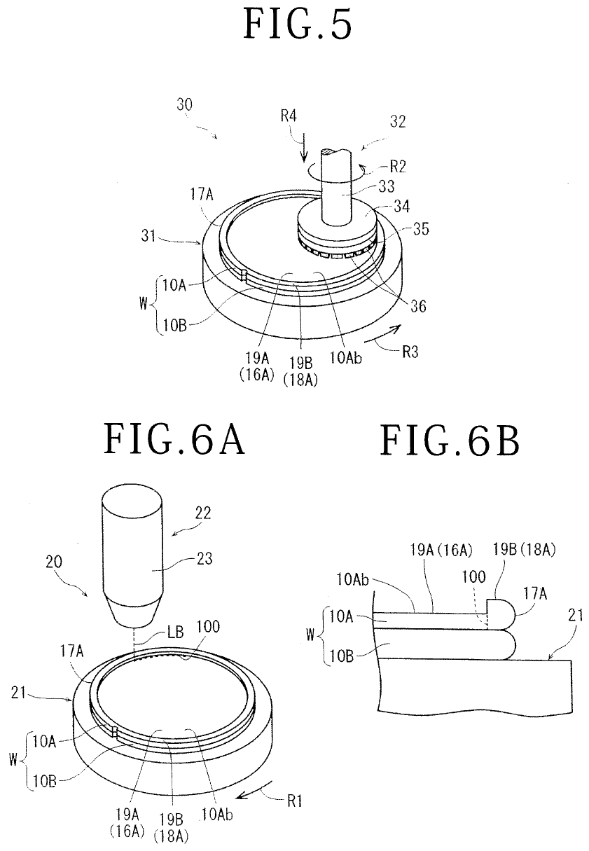

The bonded wafer W, not yet processed, as illustrated in FIG. 1 is prepared and then transported to a grinding apparatus 30 partly illustrated in FIG. 5. The grinding apparatus 30 illustrated in FIG. 5 is similar to the grinding apparatus 30 described with reference to FIG. 4 and will be omitted from detailed description below. The bonded wafer W that has been transported to the grinding apparatus 30 is placed on the chuck table 31 with the reverse side 10Ab of the first wafer 10A being exposed upwardly. Then, the suction means, not depicted, fluidly connected to the chuck table 31 is actuated to hold the bonded wafer W under suction on the chuck table 31 (holding step).

Then, as illustrated in FIG. 5, the spindle 33 is rotated about its central axis in the direction indicated by the arrow R2 at a predetermined speed of 6,000 rpm, for example. At the same time, the chuck table 31 is rotated about its central axis in the direction indicated by the arrow R3 at a predetermined speed of 300 rpm, for example. The grinding wheel 35 that is rotating in unison with the spindle 33 is lowered in the direction indicated by an arrow R4 to bring the grindstones 36 into contact with the reverse side 10Ab of the first wafer 10A. Specifically, the grindstones 36 are brought into a region of the reverse side 10Ab that is coextensive with the effective or device region 16A, and grinding-fed, i.e., lowered, in the direction indicated by the arrow R4 at a rate of 1.0 μm/s, for example. In this fashion, the grindstones 36 are kept in abrasive contact with the reverse side 10Ab of the first wafer 10. The grindstones 36 grind a central region of the reverse side 10Ab that is coextensive with the effective region 16A, forming a recess 19A to a desired depth in the central region, leaving unground an outer region of the reverse side 10Ab that is coextensive with the excessive outer circumferential region 18A including the chamfered edge 17A, as a ring-shaped ridge 19B in the outer region of the reverse side 10Ab that is raised stepwise from the bottom of the recess 19A (grinding step).

After the grinding step, the bonded wafer W with the recess 19A and the ring-shaped ridge 19B is transported to a laser processing apparatus 20 partly illustrated in FIG. 6A, where the separation initiating point forming step is carried out. The laser processing apparatus 20 illustrated in FIG. 6A is similar to the laser processing apparatus 20 described with reference to FIG. 2 and will be omitted from detailed description below.

The bonded wafer W that has been transported to the laser processing apparatus 20 is placed on the chuck table 21 with the reverse side 10Ab of the first wafer 10A facing upwardly and with the second wafer 10B facing downwardly, and the suction means, not depicted, fluidly connected to the chuck table 21 is actuated to hold the bonded wafer W under suction on the chuck table 31. Then, an alignment process is performed on the bonded wafer W held under suction on the chuck table 21, using an alignment unit and a height detector, both not depicted, of the laser processing apparatus 20. In the alignment process, the position of an outer circumferential end of the first wafer 10A where the chamfered edge 17A is located and the position of the center of the first wafer 10A are detected, the height of an upper surface as the reverse side 10Ab of the first wafer 10A is detected, and the step represented by the recess 19A and the ring-shaped ridge 19B is detected as a processing position that is to be irradiated with the laser beam LB. The processing position is established in a region on an outer circumferential side of the recess 19A in contact with the ring-shaped ridge 19B.

After the processing position to be irradiated with the laser beam LB has been detected, the chuck table 21 is moved to position the processing position immediately below the beam condenser 23 of the laser beam applying unit 22, as illustrated in FIG. 6A. Then, the laser beam LB is applied to the reverse side 10Ab of the first wafer 10A while the focused spot of the laser beam LB is being positioned within the processing position, and at the same time the chuck table 21 is rotated about its central axis in the direction indicated by the arrow R1, forming the modified layer 100 of Type 1 acting as separation initiating points within the first wafer 10A fully circumferentially along the processing position, as illustrated in FIG. 6B (separation initiating point forming step). The separation initiating points formed within the first wafer 10A are not limited to the modified layer 100 of Type 1, and may be the modified layer of Type 2 or 3, or any of other modified layers.

When the separation initiating point forming step has been carried after the grinding step, as described above, the chamfered edge removing step is carried out to apply external forces to the ring-shaped ridge 19B of the bonded wafer W where the separation initiating points are present, removing the excessive outer circumferential region 18A including the chamfered edge 17A from the bonded wafer W.

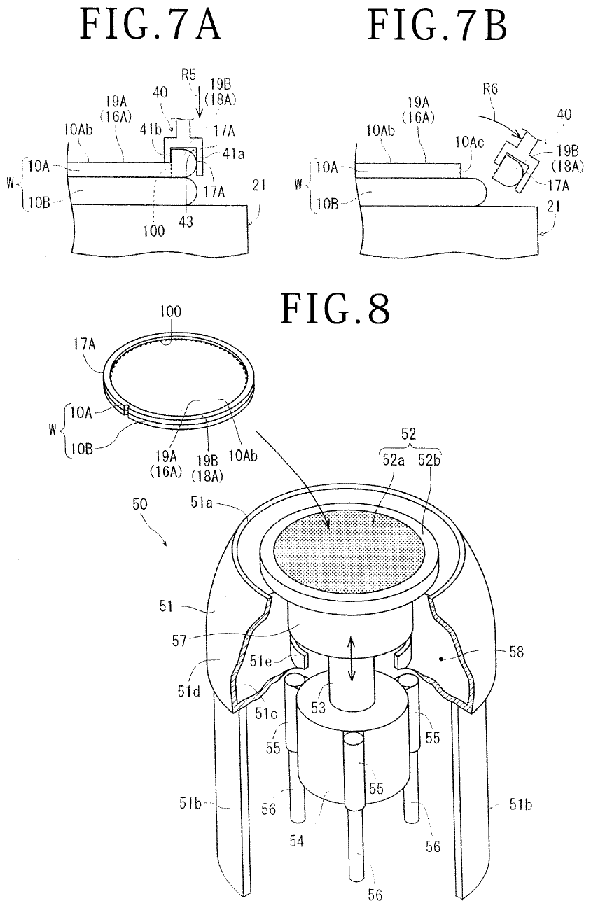

In the chamfered edge removing step carried out after the separation initiating point forming step, various kinds of means may be used for applying external forces to the ring-shaped ridge 19B. For example, external force applying means 40 illustrated in FIGS. 7A and 7B may be used. As illustrated in FIGS. 7A and 7B, the external force applying means 40 include a pair of prongs 41a and 41b on its distal end that define a housing chamber 43 therebetween for housing the ridge 19B therein. The prongs 41b is shorter than the other prong 41a to match the depth of the recess 19A, whereas the other prong 41a is longer than the prong 41b so as to be able to support the chamfered edge 17A on its outer surface. In operation, the external force applying means 40 is lowered in the direction indicated by an arrow R5, as illustrated in FIG. 7A, over the ridge 19B of the bonded wafer W after the grinding step and the separation initiating point forming step have been carried out thereon, until the housing chamber 43 accommodates the ridge 19B therein. Then, as illustrated in FIG. 7B, the external force applying means 70 is flipped over in the direction indicated by an arrow R6 to cause the prongs 41a and 41b to apply external forces to the ridge 19B, breaking the ridge 19B along the separation initiating points, i.e., the modified layer 100, and separating or removing the ridge 19B from an outer circumferential end 10Ac of the first wafer 10A. The ridge 19B separated from the outer circumferential end 10Ac of the first wafer 10A in FIG. 7B is only a part of the entire ring-shaped ridge 19B. Therefore, the chuck table 21 that is holding the bonded wafer W thereon is turned about its central axis through a predetermined angle, e.g., 45°, and then the external force applying means 40 is actuated again to remove a next part of the entire ring-shaped ridge 19B from the first wafer 10A. Subsequently, the chuck table 21 is turned through successive angles and the external force applying means 40 is actuated in successive cycles until the ring-shaped ridge 19B is entirely removed from the full circumference of the first wafer 10A.

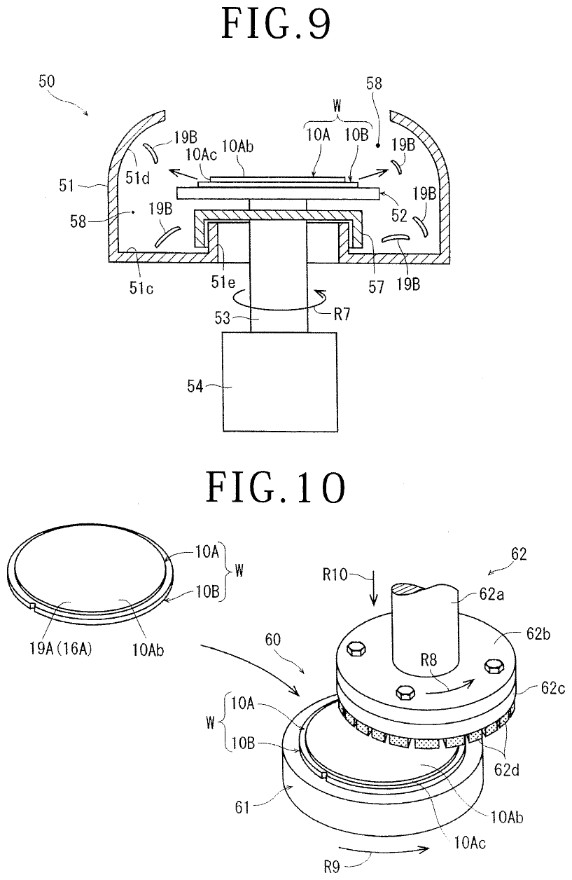

Other external force applying means than the external force applying means 40 may be used to apply external forces to the ridge 19B in the chamfered edge removing step. For example, a chamfered edge removing apparatus 50 illustrated in FIGS. 8 and 9 may be used to remove the chamfered edge 17A. As illustrated in FIGS. 8 and 9, the chamfered edge removing apparatus 50 includes a spinner table 52 for holding the bonded wafer W thereon. The spinner table 52 with the bonded wafer W held thereon rotates about its central axis at a high speed to apply centrifugal forces as external forces to the ring-shaped ridge 19B, thereby removing the chamfered edge 17A together with the excessive outer circumferential region 18A from the bonded wafer W.

As illustrated in FIG. 8, the chamfered edge removing apparatus 50 includes the spinner table 52 and a cover 51 disposed around an entire side area of the spinner table 52 and having a circular opening 51a defined in its upper end. In FIG. 8, the cover 51 has a front portion facing the viewer omitted from illustration for illustrative purposes. The spinner table 52 includes a suction chuck 52a made of a porous material permeable to air and a frame 52b surrounding the suction chuck 52a. The suction chuck 52a is fluidly connected to suction means, not depicted, and, when actuated, generates and apply a negative pressure to an upper surface of the suction chuck 52a. The spinner table 52 is coupled to an upper end of a rotatable shaft 53 whose lower end is connected to an electric motor 54. When the electric motor 54 is energized, it rotates the rotatable shaft 53 about its central axis, rotating the spinner table 52 about its central axis. A plurality of air cylinders 55 are mounted at spaced intervals on an outer circumferential surface of the electric motor 54. When the air cylinders 55 are actuated, they selectively push and pull respective rods 56 vertically, thereby lifting and lowering the spinner table 52, the rotatable shaft 53, and the electric motor 54 together. The rotatable shaft 53 and the electric motor 54 also function as a base supporting the spinner table 52 thereon.

The cover 51 includes an annular bottom wall 51c, an outer wall 51d erected from an outer circumferential edge of the bottom wall 51c, and an inner wall 51e erected from an inner circumferential edge of the bottom wall 51c, the bottom wall 51c, the outer wall 51d, and the inner wall 51e jointly defining an inner space 58 of the cover 51. The chamfered edge removing apparatus 50 also includes a plurality of legs 51b supporting the cover 51 on their upper ends. The outer wall 51d is shaped as a dome wall that is gradually reduced in diameter in an upward direction. The circular opening 51a that is defined by the upper end of the outer wall 51d is slightly larger in diameter than the frame 52b of the spinner table 52. The spinner table 52 is disposed on a skirt 57 mounted on the rotatable shaft 53 for rotation therewith. The chamfered edge removing apparatus 50 that is of the structure described above is used to carry out the chamfered edge removing step as described below with reference to FIGS. 8 and 9. In FIG. 9, the cover 51 and the skirt 57 are depicted in cross section, and the legs 51b and the air cylinders 55 are omitted from illustration for illustrative purposes.

In preparation for the chamfered edge removing step, the air cylinders 55 are actuated to lift the spinner table 52 in the inner space 58 of the cover 51 to a position near the opening 51a in the cover 51 where the bonded wafer W is to be loaded into and unloaded from the chamfered edge removing apparatus 50. Then, the bonded wafer W having the recess 19A and the ring-shaped ridge 19B formed and also having the modified layer 100 formed as separation initiating points is transported to the chamfered edge removing apparatus 50. The bonded wafer W is placed on the spinner table 52 with the first wafer 10A facing upwardly and the second wafer 10B facing downwardly, and the non-illustrated suction means fluidly connected to the spinner table 52 is actuated to hold the bonded wafer W under suction on the spinner table 52.

Then, the air cylinders 55 are actuated to lower the spinner table 52 to a chamfered edge removing position in a lower portion of the inner space 58, as illustrated in FIG. 9. At this time, the skirt 57 covers an outer side of the inner wall 51e of the cover 51.

Then, the electric motor 54 is energized to rotate the rotatable shaft 53 in the direction indicated by an arrow R7 in FIG. 9 at a high speed for a predetermined period of time. The high speed at which the rotatable shaft 53 rotates is in the range from 1,000 to 3,000 rpm, for example. When the rotatable shaft 53 rotates at the high speed, the spinner table 52 also rotates at the high speed, effectively applying strong centrifugal forces as external forces to the ring-shaped ridge 19B of the first wafer 10A. When the external forces are applied, the ring-shaped ridge 19B is broken along the separation initiating points, i.e., the modified layer 100, in the first wafer 10A, into fragments that are scattered from the outer circumferential end 10Ac of the first wafer 10A into the inner space 58 of the cover 51. As a result, the ring-shaped ridge 19B of the excessive outer circumferential region 18A including the chamfered edge 17A is removed from the effective region 16A of the first wafer 10A, whereupon the chamfered edge removing step is completed. At this time, since the outer wall 51d of the cover 51 is gradually reduced in diameter in the upward direction, the scattered fragments of the ring-shaped ridge 19B fall down an inner surface of the outer wall 51d and are prevented from jumping out of the cover 51 through the opening 51a. The fragments of the ring-shaped ridge 19B removed from the first wafer 10A are collected on the bottom wall 51c of the cover 51. After the chamfered edge removing step has been carried out on a plurality of bonded wafers W, the collected fragments of the ring-shaped ridges 19B are periodically retrieved from the chamfered edge removing apparatus 50.

When the chamfered edge removing step has been completed, a finishingly grinding step may be carried out on the reverse side 10Ab of the first wafer 10A to reduce the thickness of the bonded wafer W to a desired thickness. A process of grinding the reverse side 10Ab of the first wafer 10A to reduce the thickness of the bonded wafer W from which the ring-shaped ridge 19B has been removed in the chamfered edge removing step to a desired thickness in the finishingly grinding step will be described below.

The bonded wafer W on which the chamfered edge removing step has been carried out is transported to a grinding apparatus 60 partly illustrated in a right section of FIG. 10. As illustrated in FIG. 10, the grinding apparatus 60 includes a grinding unit 62 for thinning down a workpiece held under suction on a chuck table 61. The grinding unit 62 includes a rotatable spindle 62a that is rotatable about its central axis by a rotating mechanism, not depicted, a wheel mount 62b mounted on a lower distal end of the rotatable spindle 62a and rotatable about its central axis upon rotation of the rotatable spindle 62a, and a grinding wheel 62c mounted on a lower surface of the wheel mount 62b, with an annular array of grindstones 62d securely disposed on a lower surface of the grinding wheel 62c.

As illustrated in FIG. 10, the bonded wafer W is transported to the grinding apparatus 60 and placed on the chuck table 61 with the second wafer 10B facing downwardly. The bonded wafer W is then held under suction on the chuck table 61 by suction means, not depicted, fluidly connected to the chuck table 61. Then, the rotatable spindle 62a of the grinding unit 62 is rotated about its central axis in the direction indicated by an arrow R8 at a predetermined speed of 6,000 rpm, for example. At the same time, the chuck table 61 is rotated about its central axis in the direction indicated by an arrow R9 at a predetermined speed of 300 rpm, for example. Then, while grinding water is being supplied to the reverse side 10Ab of the first wafer 10A from grinding water supply means, not depicted, the grinding wheel 62c is lowered in the direction indicated by an arrow R10 to bring the grindstones 62d into contact with the reverse side 10Ab, and grinding-fed, i.e., lowered, in the direction indicated by the arrow R10 at a rate of 1.0 μm/s, for example, grinding the reverse side 10Ab. At this time, the reverse side 10Ab may be ground while the thickness of the bonded wafer W is being measured by a contact-type or non-contact-type measurement gauge, not depicted. When the grindstones 62d have ground the reverse side 10Ab to a predetermined depth to reduce the thickness of the bonded wafer W to a desired finished thickness, the grinding unit 62 stops its grinding operation and is then lifted, whereupon the finishingly grinding step is completed. When the finishingly grinding step has been completed, additional steps including a cleaning step and a drying step, for example, omitted from detailed description, will be carried out on the bonded wafer W.

As described above, the bonded wafer W on which the grinding step and the separation initiating point forming step of the method of processing a wafer according to the present embodiment have been carried out has the recess 19A formed in the region of the reverse side 10Ab of the first wafer 10A that is coexistent with the effective region 16A, leaving the ring-shaped ridge 19B that is made up of the excessive outer circumferential region 18A including the chamfered edge 17A. It is relatively easy to remove the ring-shaped ridge 19B made up of the excessive outer circumferential region 18A including the chamfered edge 17A from the remainder of the first wafer 10A that includes the recess 19A. Therefore, the difficulty in removing the excessive outer circumferential region 18A including the chamfered edge 17A is eliminated.

Inasmuch as it is easy to remove the chamfered edge 17A, the chamfered edge 17A is prevented from remaining on the outer circumference of the first wafer 10A. Accordingly, the problems of a part of the chamfered edge 17A left on the first wafer 10A and falling off as a contaminant or being responsible for chippings from individual device chips at the time the bonded wafer W is divided into those device chips are solved.

In the embodiment described above, the method of processing a wafer is applied to the bonded wafer W. However, a wafer that can be processed by the method of processing a wafer according to the present invention is not limited to not the bonded wafer W, but may be the simplex wafer 10C illustrated in FIG. 1B, or may be any of various wafers each having an effective region and an excessive outer circumferential region surrounding the effective region with a chamfered edge formed on the outer circumference of the excessive outer circumferential region. For example, wafers that are applicable to the method of processing a wafer according to the present invention may include a wafer of GaN, a wafer of GaAs, a wafer of LiTaO₃, a wafer of LiNbO₃, or a wafer such as a glass wafer whose central region referred to as an effective region is free of devices and that will subsequently be processed into products.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of processing a wafer having on a face side thereof an effective region and an excessive outer circumferential region surrounding the effective region with a chamfered edge formed on an outer circumference of the excessive outer circumferential region, the method comprising:
a holding step of holding the wafer on a chuck table while exposing a reverse side of the wafer;
a grinding step of grinding the reverse side of the wafer with a grinding wheel that has an annular array of grindstones and that is smaller in diameter than the wafer, while positioning the grinding wheel radially inwardly of the excessive outer circumferential region, thereby grinding the effective region to a predetermined thickness to leave the excessive outer circumferential region as a ring-shaped ridge;
before or after the grinding step, a separation initiating point forming step of forming separation initiating points in the wafer for separating the excessive outer circumferential region from the effective region; and
a chamfered edge removing step of applying external forces to the ring-shaped ridge of the wafer in which the separation initiating points have been formed, to remove the chamfered edge together with the excessive outer circumferential region from the wafer.

2. The method of processing a wafer according to claim 1, wherein
the chamfered edge removing step includes
holding the wafer on a spinner table and rotating the spinner table to apply centrifugal forces as the external forces to the ring-shaped ridge to remove the chamfered edge together with the excessive outer circumferential region from the wafer.

3. The method of processing a wafer according to claim 1, wherein
the separation initiating point forming step is carried out before the grinding step, and
the grinding step includes
applying external forces from the grinding wheel to the ring-shaped ridge of the wafer to remove the chamfered edge together with the excessive outer circumferential region from the wafer.

4. The method of processing a wafer according to claim 1, wherein
the wafer is a bonded wafer including a wafer having the effective region and another wafer bonded to the wafer with the effective region facing the other wafer.

5. The method of processing a wafer according to claim 1, wherein
the separation initiating point forming step includes
applying a laser beam having a wavelength transmittable through the wafer to the wafer while positioning a focused spot of the laser beam in a boundary zone between the effective region and the excessive outer circumferential region, to form a ring-shaped modified layer in the boundary zone.

6. The method of processing a wafer according to claim 1, further comprising:
after the chamfered edge removing step, a finishingly grinding step of further grinding the reverse side of the wafer to reduce a thickness of the wafer to a predetermined finished thickness.

7. The method of processing a wafer according to claim 1, wherein
the effective area of the wafer is a device region including a plurality of devices formed in respective areas demarcated by a grid of projected dicing lines.
